(19) United States
(12) Patent Application Publication
(10) Pub. No.: US 2007/0243666 A1
(43) Pub. Date: Oct. 18, 2007

(54) Semiconductor package, array arranged substrate structure for the semiconductor package and fabrication method of the semiconductor package

(75) Inventors: Chien-Ping Huang, Taichung (TW); Chien-Chih Chen, Taichung (TW); Yu-Chieh Tsai, Taichung (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/725,512

(22) Filed: Mar. 19, 2007

(30) Foreign Application Priority Data
Apr. 18, 2006 (TW) 095113768

(51) Int. Cl. H01L 21/00

(52) U.S. Cl. 438/127

(57) ABSTRACT

A semiconductor package, an array arranged substrate structure for the semiconductor package, and fabrication method of the semiconductor package are disclosed. First, a substrate having a plurality of array arranged substrate units is provided, and electroplating buses are formed between the substrate units. Each substrate unit has a plurality of electrically connecting pads and a plurality of conductive traces for connecting the electrically connecting pads to the electroplating buses such that an electroplating metallic layer can be formed on the electrically connecting pads via the electroplating buses and the conductive traces. Then, slots are further formed between the substrate units for disconnecting connections between the conductive traces and the electroplating buses, thus, enable each of the substrate units to become electrically independent from each other for a pre-proceeding electrical O/S test. Moreover, the slots are filled with a filling material such as an insulating gel or an encapsulant during a Molding process. Further, a cutting process is performed between the substrate units through the filling material or encapsulant filling the slots upon completion of encapsulation. Thus, the cutting surface can be kept smooth and exposure of conductive traces from the cutting surface is avoided, thereby preventing static electricity and humidity from adversely affecting the product quality.

### BACKGROUND OF THE INVENTION

1. Field of the Invention

The present invention relates generally to semiconductor packages and substrate structures thereof and methods for fabricating the same, and more particularly to an array arranged substrate structure with electroplating buses disposed thereon, a semiconductor package thereof and a method for fabricating the same.

2. Description of Related Art

With rapid growth of various kinds of portable products related to communications, networks and computers, ball grid array (BGA) semiconductor packages with reduced integrated circuit (IC) area, high density and multiple leads have become a mainstream on packaging markets. To obtain a BGA semiconductor package, a semiconductor chip is mounted and electrically connected to one side of a substrate. The other side of the substrate has a plurality of grid array arranged solder balls by which electrical connection can be made to external circuitry. Such a package structure allows more I/O connections per unit area to be formed on the chip carrier for meeting demands for highly integrated semiconductor chips.

In order to further improve semiconductor package product yield, reduce fabrication cost, and improve substrate utilization while meeting the demands for lighter, thinner, shorter and smaller electronic products, U.S. Pat. No. 5,776,798 discloses a Thin & Fine BGA (TFBGA) semiconductor package with a even smaller package size, wherein a plurality of array arranged package regions is predetermined on a substrate so as to respectively define positions of TFBGA package units, then after performing chip mounting, wire bonding and molding processes, a singulation process is performed so as to separate the packaging regions with the semiconductor chips mounted thereon from each other, thereby obtaining a plurality of single TFBGA package units.

In addition, a Ni/Au metallic layer is formed on exposed surfaces of electrically connecting pads such as bonding fingers or ball pads disposed on substrate surface so as to provide electrical coupling between conductive components such as gold wires, bumps or solder balls and chips or substrates and meanwhile protect the electrically connecting pads from being oxidized. The metallic layer with high conductivity is mainly fabricated by connecting the electrically connecting pads with an electroplating bus during the substrate circuit layout such that electroplating current can flow through the electroplating bus and reaches the electrically connecting pads, thereby depositing such as a Ni/Au metallic layer on the electrically connecting pads. After the packaging process, the electroplating bus can be removed.

FIG. 1 shows a semiconductor package substrate such as a TFBGA substrate arranged in a batch-type array. As shown in FIG. 1, a plurality of array arranged substrate units 10 are defined by a plurality of horizontal cutting lines SLx and vertical cutting lines SLy. The substrate units 10, i.e. packaging regions in subsequent processes, are separated from each other by cutting along the cutting lines SLx and Sly during the final cutting process. A plurality of electroplating buses 14 are disposed between adjacent substrate units 10. The circuitry of the substrate unit 10 comprises a plurality of bonding fingers 11 disposed on the front side of the substrate, a plurality of ball pads (not shown) disposed on the back side of the substrate and a plurality of conductive traces 13 electrically connecting the bonding fingers 1 and the ball pads with the electroplating buses 14, allowing electroplating current to flow through the electroplating buses 14 and the conductive traces 13 and reaches the bonding fingers 11 on the front side of the substrate 10 and the ball pads on the back side of the substrate 10, so as to form a Ni/Au metallic layer on the bonding fingers 11 and the ball pads. Therein, the electroplating buses 14 are arranged as a grid shape and located within the cutting lines SLx and Sly such that the electroplating buses 14 can be removed through the cutting process. Related technique is disclosed in U.S. Pat. Nos. 6,281,047, No. 6,319,750, and No. 6,479,894.

Further, semiconductor package substrates can be applied in various electronic products such as small sized memory cards. For example, Micro secure digital card (Micro SD card) is a high volume flash memory circuit module that can be coupled with an electronic data platform such as personal computers, personal digital assistant devices, digital cameras, multimedia browsers and so on for storing various digital type multimedia data such as digital photo data, video data or audio data.

As disclosed by U.S. Patent Publication No. 2004/0259291, after a molding process is completed, a laser cutting process is performed so as to form a plurality of irregular Micro SD memory card packages. As the laser cutting path needs to pass through different materials such as encapsulant, solder mask layer, conductive traces, electroplating buses and so on, cutting surface is easy to be burned, thus causing such problems such as irregular shapes and uneven cutting surface.

Further, after the cutting process is completed, the conductive traces can be exposed from the cutting surface of the semiconductor package. As a result, external moisture can invade into the package along the exposed conductive traces and thus leads to poor product reliability. Moreover, due to such problem as ESD, it is easy for the exposed cutting wires to conduct static current into the package, thereby causing a damage to the chip.

In addition, as circuits of the substrate units are bused together before the cutting process being implemented, the process of electrical Open/Short (O/S) test to each substrate unit for examining the possibility of faulty electrical connection such as short circuit is not allowed until the processes of packaging the chip is completed. If any faulty electrical connections have been found for the substrate, the packaged chip is to be discarded, and as a result the fabrication cost is undesirably increased. To solve the above-described problem, a substrate without electroplating buses is disclosed such as U.S. Pat. Nos. 6,576,540 and 6,853,084. However, such a process is complex and the cost-ineffective, which is about 1.3 to 1.8 times higher than the cost of the conventional process using electroplating buses.

Therefore, there is a need to provide a semiconductor package, a chip carrier structure for the semiconductor package and a fabrication method of the semiconductor package, through which the above-described problems such as exposure of conductive traces from the cutting surface, ESD damage problem, cutting surface burning and unevenness can be prevented and meanwhile electrical test can be pre-performed to substrate units so as to keep the fabrication process cost-effective.

### SUMMARY OF THE INVENTION

According to the above drawbacks, an objective of the present invention is to provide a semiconductor package, an array arranged substrate structure and a fabrication method thereof for preventing the conductive traces from exposure.

Another objective of the present invention is to provide a semiconductor package, an array arranged substrate structure and a fabrication method thereof, allowing an electrical O/S test can be performed to the substrate units in advance so as to prevent a waste in material for subsequent processes and an increase in cost.

A further objective of the present invention is to provide a semiconductor package, an array arranged substrate structure and a fabrication method thereof, by which ESD damage problem can be prevented.

Still another objective of the present invention is to provide a semiconductor package, an array arranged substrate structure and a fabrication method thereof, by which the problems of burning and unevenness on the laser cutting surfaces can be prevented.

A further objective of the present invention is to provide a semiconductor package, an array arranged substrate structure and a fabrication method thereof, which provides a cost-effective means for mass production.

In order to attain the above and other objectives, according to a preferred embodiment, a fabrication method of a semiconductor package is disclosed, which comprises the steps of: providing a substrate having a plurality single substrate units arranged in array, wherein electroplating buses are disposed between adjacent substrate units, and each substrate unit has a plurality of electrically connecting pads and a plurality of conductive traces for electrically connecting the electrically connecting pads with the electroplating buses; performing an electroplating process to electroplate a metallic layer on the electrically connecting pads via the electroplating buses and the conductive traces; forming slots between the substrate units, each of which breaks the connection between the conductive traces and the electroplating buses; filling an insulating gel in the slots and performing a drying process to the insulating gel; mounting and electrically connecting a semiconductor chip to each of the substrate units; performing a molding process so as to form an encapsulant encapsulating the semiconductor chips on the substrate; and performing a cutting process along the cutting line between the substrate units, passing through the slots so as to form a plurality of semiconductor packages. In the cutting process, the width of the cutting path is smaller than the width of the slot, so that only the filling material in the slot is being cut, preventing the conductive traces to be exposed therefrom. The fabrication method can be applied in a TFBGA semiconductor package or a Micro SD card package.

According to another preferred embodiment of the present invention, the fabrication method of a semiconductor package comprises the steps of: providing a substrate having a plurality single substrate units arranged in array, wherein electroplating buses are disposed between adjacent substrate units, and each substrate unit has a plurality of electrically connecting pads and a plurality of conductive traces for electrically connecting the electrically connecting pads with the electroplating buses; performing an electroplating process to electroplate a metallic layer on the electrically connecting pads via the electroplating buses and the conductive traces; forming slots between the substrate units, each of which breaks the connection between the conductive traces and the electroplating buses; mounting and electrically connecting a semiconductor chip to each of the substrate units; performing a Molding process so as to form an encapsulant encapsulating the semiconductor chips on the substrate allowing the slots to be filled by the encapsulant; and performing a cutting process along the cutting line between the substrate units, passing through the slots so as to form a plurality of semiconductor packages.

Through the foregoing fabrication method, an array arranged substrate structure disclosed by the invention, comprises: a plurality of array arranged substrate units, wherein each substrate unit has a plurality of electrically connecting pads; a plurality of electroplating buses arranged in a grid between the substrate units, each of which has conductive traces formed thereon for electrically connecting the electrically connecting pads with the electroplating buses; and a plurality of slots formed between the substrate units which break connections between the conductive traces and the electroplating buses. The substrate structure can further comprise a filling material such as an insulating gels or an encapsulant filled in the slots.

Also, the present invention discloses a semiconductor package, comprising: a substrate unit with a plurality of slots formed at least around part of the periphery thereof, a filling material being filled in the slots; a semiconductor chip mounted on and electrically connected with the substrate unit; and an encapsulant formed on the substrate unit for encapsulating the semiconductor chip. The filling material can be an insulating gel or an encapsulant.

Therefore, the present invention mainly provides a substrate having a plurality of array arranged substrate units; forms a Ni/Au electroplating metallic layer on the electrically connecting pads of the substrate units via electroplating buses between the substrate units and conductive traces of the substrate units; and forms slots between the substrate units with the slots cutting connections between the electroplating buses and the conductive traces for making the substrate units become independent from each other such that an electrical O/S test can be pre-performed on each of the substrate units before the chip mounting and Molding process, thereby saving material cost and fabrication cost.

Further, since the slots is are pre-filled with a filling material such as an insulating gel or an encapsulant formed through the Molding process, and since width of the slots is bigger than that of the cutting path, after a cutting process is performed between the substrate units along the cutting path passing through the insulating gel or encapsulant of the slots, the cutting surface is kept smooth and exposure of the conductive traces from the cutting surface is avoided, thereby preventing static electricity and humidity from adversely affecting the product quality. Especially if a laser cut is applied, as the cutting path passes through less part of the substrate unit, such problems as laser melting problem and uneven cutting surface can be avoided.

### BRIEF DESCRIPTION OF DRAWINGS

FIG. 1 is a diagram of a conventional batch-type arranged substrate;

FIGS. 2A to 2F are diagrams showing a semiconductor package, an array arranged substrate structure for the semiconductor package and fabrication method of the semiconductor package according to a first embodiment of the present invention;

FIG. 2C′ is a diagram showing a tape being adhered to bottom of the substrate during fabricating the semiconductor package;

FIGS. 3A to 3D are diagrams showing a semiconductor package and fabrication method thereof according to a second embodiment of the present invention;

FIGS. 4A to 4C are diagrams showing a semiconductor package and fabrication method according to a third embodiment of the present invention; and

FIG. 5 is a diagram showing an array arranged substrate structure according to a fourth embodiment of the present invention.

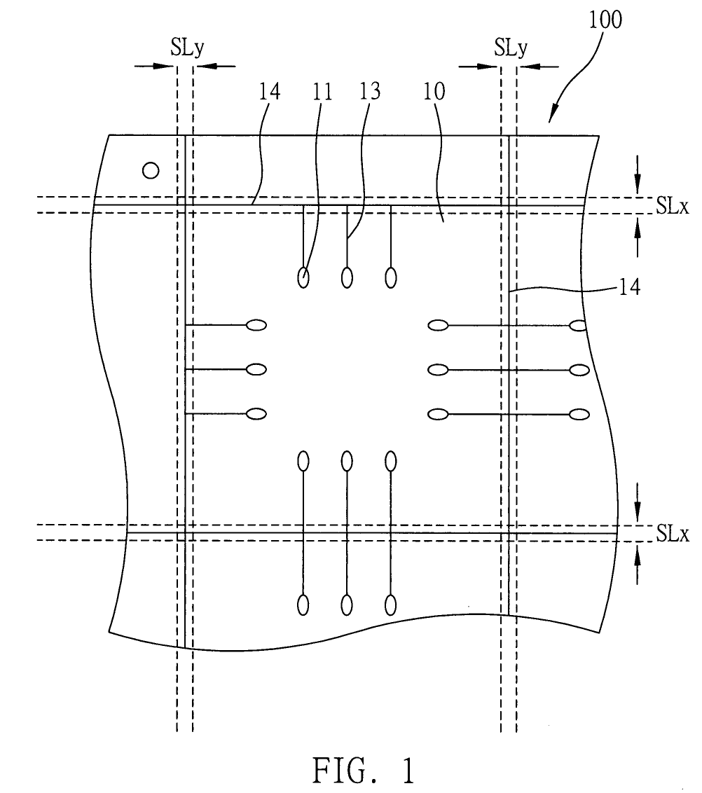

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

### First Embodiment

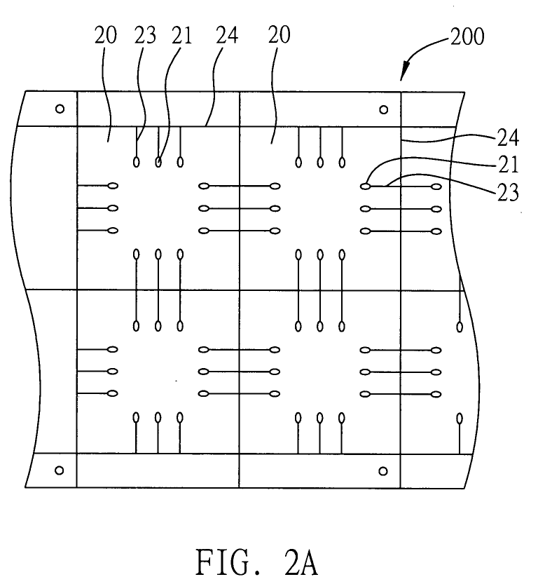

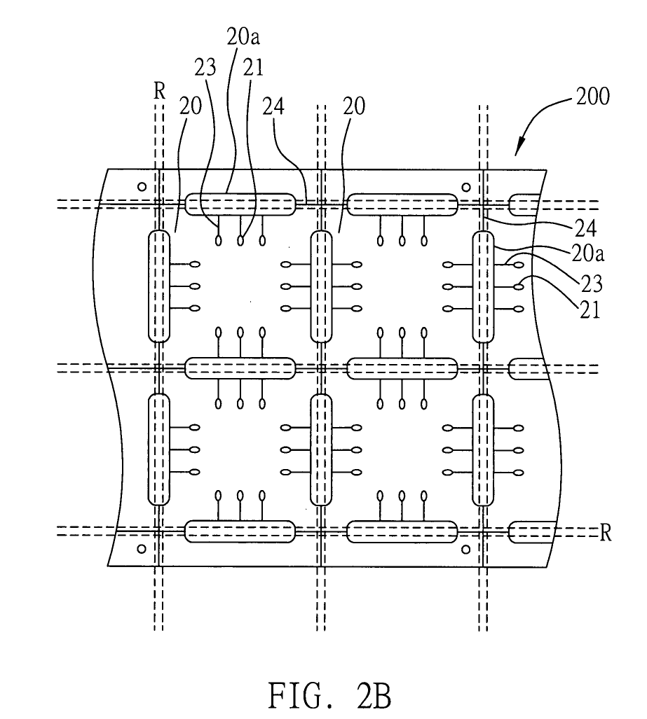

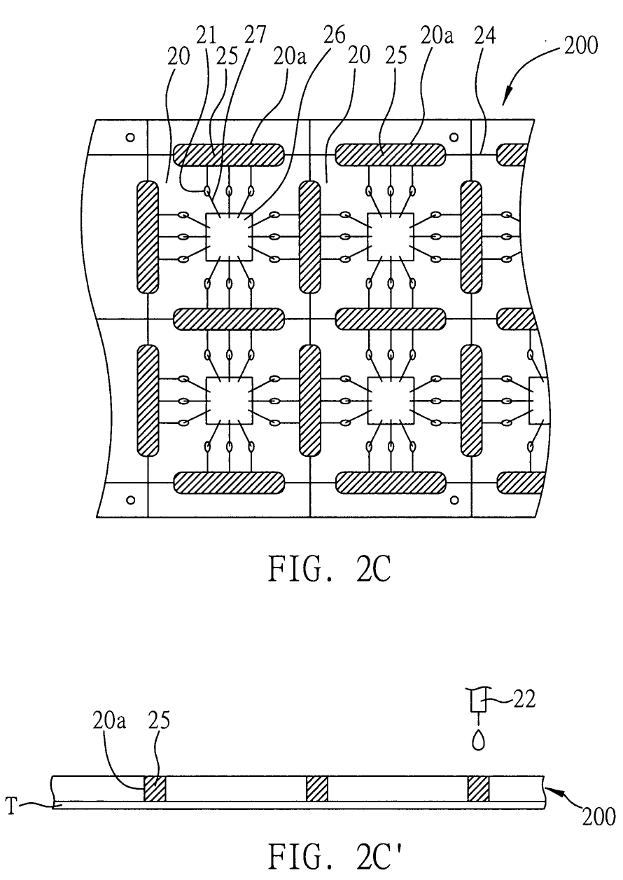

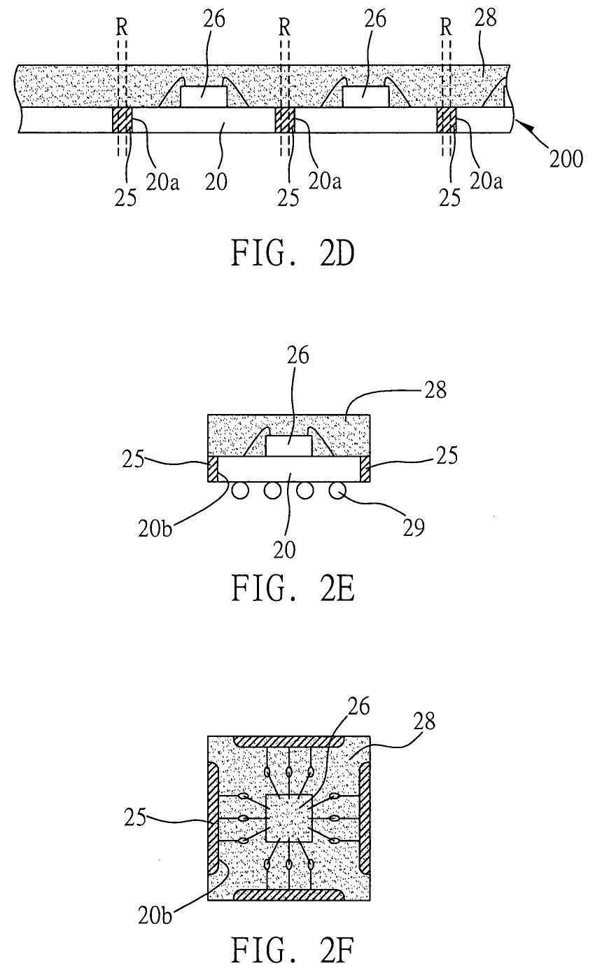

FIGS. 2A to 2F are diagrams showing a semiconductor package, an array arranged substrate structure and fabrication method thereof according to a first embodiment of the present invention. The semiconductor package can be a TFBGA semiconductor package.

As shown in FIG. 2A, firstly, a substrate 200 having a plurality of array arranged substrate units 20 is provided. Electroplating buses 24 are disposed between the adjacent substrate units 20. Each substrate unit 20 has a plurality of electrically connecting pads 21 and a plurality of conductive traces 23 for electrically connecting the electrically connecting pads 21 with the electroplating buses 24 so as to form a Ni/Au electroplating metallic layer (not shown) on the electrically connecting pads 21 via the electroplating buses 24 and the conductive traces 23. The electrically connecting pads 21 are used for establishing electrical connections between semiconductor chips and the substrate.

As shown in FIG. 2B, a plurality of slots 20a are formed between the substrate units 20, wherein the slots 20a breaks the electrical connections between the conductive traces 23 and the electroplating buses 24. Particularly, it should be noted that width of the slots 20a is larger than width of the cutting path R (as shown in dashed lines) between the adjacent substrate units 20.

As shown in FIG. 2C, subsequent processes involve filling and drying of the filling material. The filling material 25 such as an insulating gel filled within the Au wires 20a can be made of a polymer such as an epoxy resin. After the drying process, a semiconductor chip 26 is then mounted on each of the substrate units 20 and electrically connected with the electrically connecting pads 21 of the substrate unit through a plurality of solder wires 27. In addition, a tape T (as shown in FIG. 2C′) can be adhered to the bottom of the substrate in advance for covering one side of the slots 20a such that a dispenser 22 can be used to fill the filling material 25 inside the slots 20a. After the process of drying the filling material is completed, the tape T can be removed.

As shown in FIG. 2D, a Molding process is then performed to form an encapsulant 28 encapsulating the semiconductor chips 26 on the substrate 200. Further referring to FIG. 2E, a cutting process is performed between the substrate units 20 along the cutting path passing through the filling material 25 inside the slots 20a. Moreover, a plurality of solder balls 29 can further be mounted on bottom of the substrate units. Thus, a plurality of semiconductor packages is obtained, wherein each of the semiconductor packages has a semiconductor chip 26 encapsulated therein and a plurality of slots 20b formed at least around part of the periphery of the substrate unit 20 and filled with a filling material 25. The completed semiconductor package is shown in FIG. 2F.

Through the above-described fabrication method, the present invention also discloses an array arranged substrate structure, which comprises: a plurality of array arranged substrate units 20, wherein each substrate unit 20 has a plurality of electrically connecting pads 21; electroplating buses 24 arranged in a grid between the substrate units 20, each of which has conductive traces 23 formed thereon for electrically connecting the electrically connecting pads 21 with the electroplating buses 24; and a plurality of slots 20a formed between the substrate units 20 for breaking the electrical connections between the conductive traces 23 and the electroplating buses 24. Further, the substrate structure comprises a filling material 25 such as an insulating gel filled inside the slots 20a.

The present invention also discloses a semiconductor package, which comprises: a substrate unit 20 having a plurality of slots 20b filled by a filling material on at least a part of the periphery thereof; a semiconductor chip 26 mounted on and electrically connected with the substrate unit 20; and an encapsulant 28 formed on the substrate unit 20 for encapsulating the semiconductor chip 26. In addition, the semiconductor package comprises a plurality of solder balls 29 mounted on bottom of the substrate unit 20.

### Second Embodiment

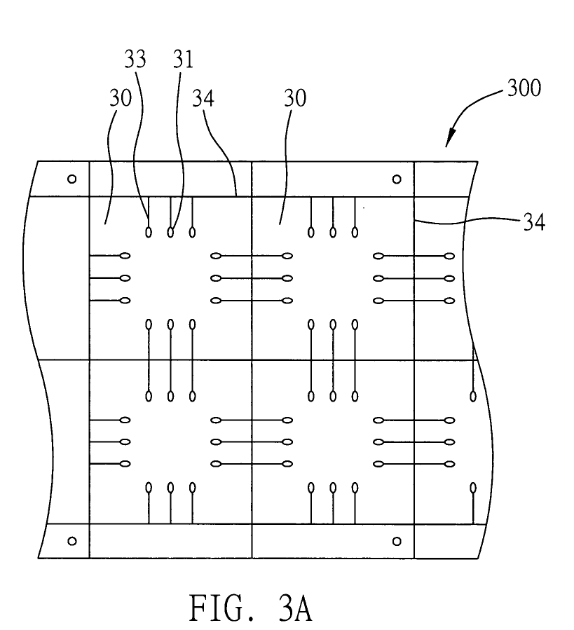

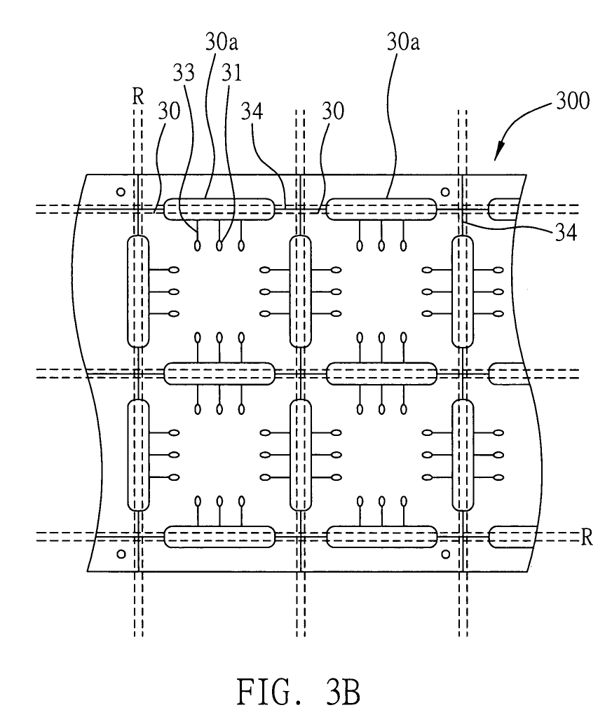

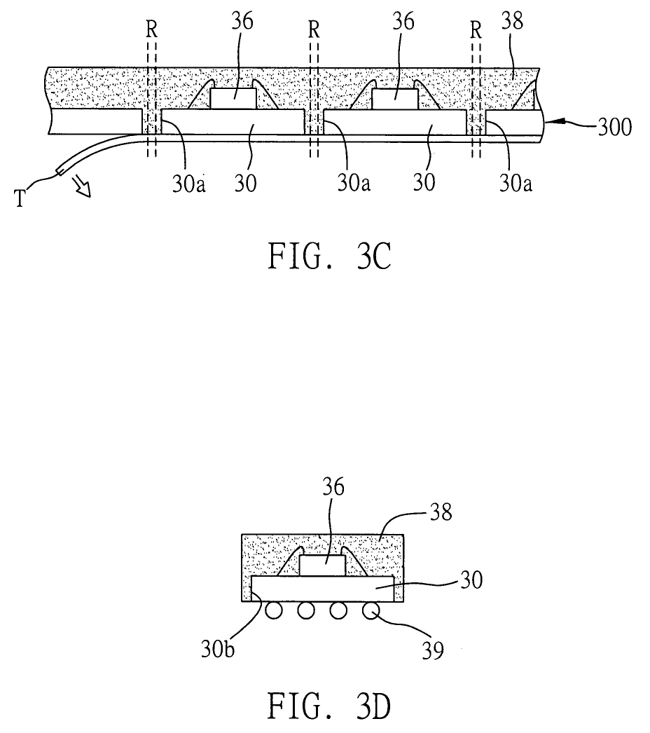

FIGS. 3A to 3D are diagrams showing a semiconductor package and fabrication method thereof according to a second embodiment of the present invention. As shown in FIG. 3A, a substrate 300 having a plurality of array arranged substrate units 30 is provided. Electroplating buses 34 are disposed between the substrate units 30. Each substrate unit 30 has a plurality of electrically connecting pads 31 and a plurality of conductive traces 33 for electrically connecting the electrically connecting pads 31 with the electroplating buses 34 so as to form a Ni/Au electroplating metallic layer (not shown) on the electrically connecting pads 31 via the electroplating buses 34 and the conductive traces 33.

As shown in FIG. 3B, a plurality of slots 30a is formed between the substrate units 30, wherein the slots 30a break the electrical connections between the conductive traces 33 and the electroplating buses 34. The width of the slots 30a is larger than width of the cutting path R (as shown in dashed lines) between the adjacent substrate units 30.

As shown in FIG. 3C, a semiconductor chip 36 is then mounted on and electrically connected with each of the substrate units 30. Subsequently, an encapsulant 38 is formed on the substrate 300 through a Molding process, encapsulating the semiconductor chips 36 and filling the slots 30a.

In addition, a tape T can be adhered to the bottom of the substrate in advance for covering one side of the slots 30a so as to allow the encapsulant 38 to fill the slots 30a without encapsulant bleeding over to the bottom of the substrate. After the Molding process is completed, the tape T can be removed.

As shown in FIG. 3D a cutting process is performed between the substrate units 30 along the cutting path passing through the slots 30a. After a plurality of solder balls 39 are mounted on the bottom of the substrate units 30, a plurality of semiconductor packages are obtained. In each of the semiconductor packages, the semiconductor chip 36 is encapsulated and a plurality of slots 30b filled with the encapsulant 38 are formed on at least a part of the periphery of the substrate unit 30.

### Third Embodiment

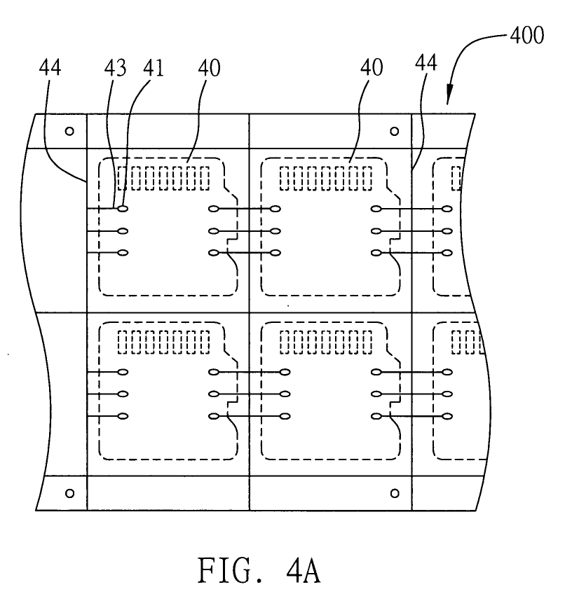

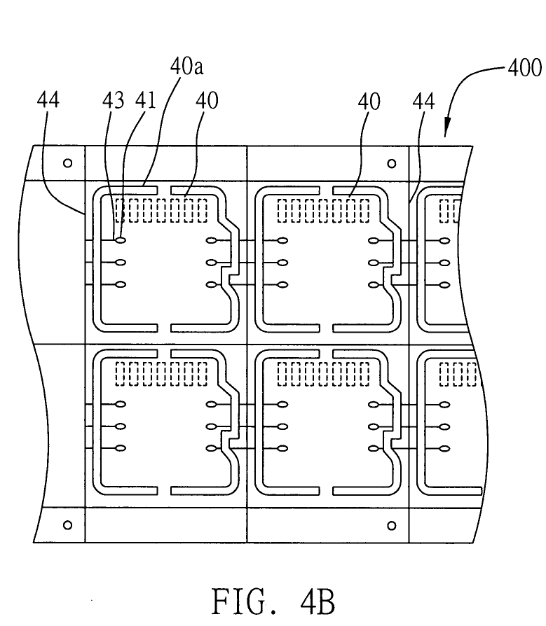

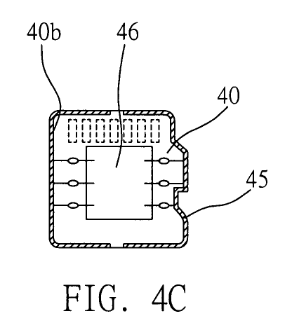

FIGS. 4A to 4C are diagrams showing a semiconductor package and fabrication method thereof according to a third embodiment of the present invention. The main difference of the present embodiment from the above-described embodiments is the semiconductor package and fabrication method thereof are applied in a memory card package according to the present embodiment.

As shown in FIG. 4A, a substrate 400 having a plurality of array arranged substrate units 40 is provided, wherein each substrate unit 40 is used for building a Micro SD memory card package. Electroplating buses 44 are disposed between the substrate units 40. Each substrate unit 40 has a plurality of electrically connecting pads 41 and a plurality of conductive traces 43 for electrically connecting the electrically connecting pads 41 with the electroplating buses 44 so as to form an electroplating metallic layer (not shown) on the electrically connecting pads 41 via the electroplating buses 44 and the conductive traces 43.

As shown in FIG. 4B, slots 40a are formed between the substrate units 40, wherein the slots 40a breaks the electrical connections between the conductive traces 43 and the electroplating buses 44. The slots 30a correspond in shape to the Micro SD memory card package.

As shown in FIG. 4C, a semiconductor chip 46 is mounted on and electrically connected with each of the substrate units 40. Then, an encapsulant is formed on the substrate 400 through a Molding process for encapsulating the semiconductor chips 46 and filling the slots 40a. Subsequently, a laser cutting process is performed between the substrate units along the cutting path passing through the slots so as to form a plurality of Micro SD memory card packages.

In addition, the slots between the substrate units can be pre-filled with a filling material such as an insulating gel. Thus, after the cutting process, the slots 40b filled with the filling material 45 such as the insulating gel are located on at least a part of the periphery of the package.

### Fourth Embodiment

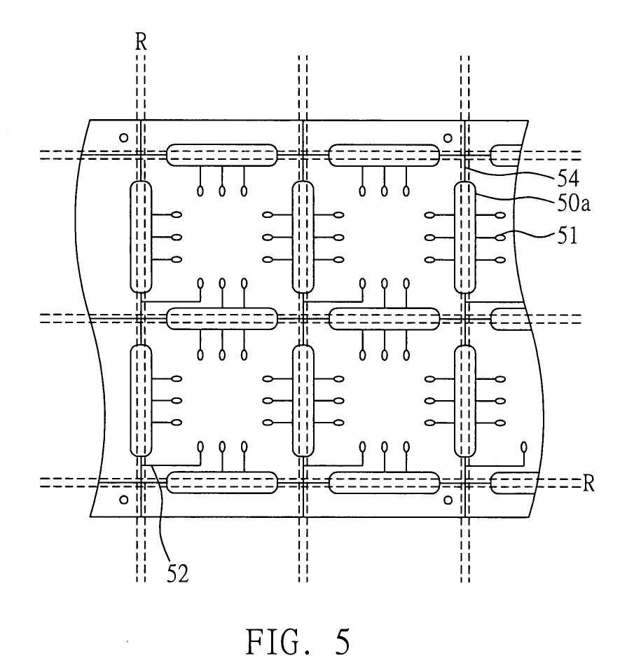

FIG. 5 is a diagram of an array arranged substrate structure according to a fourth embodiment of the present invention. The main difference of the present embodiment from the previous embodiments is ground traces 52 that are connected with the electroplating buses 54 are designed to be located outside the slots 50a and prevented from being cut off in forming the slots 50a, thus a the non-sticking test of the electrical connection between the semiconductor chip and the electrically connecting pads 51 during wire bonding process can be performed.

Therefore, the substrate having a plurality of array arranged substrate units involves forming a Ni/Au electroplating metallic layer on the electrically connecting pads of the substrate units via electroplating buses between the substrate units and conductive traces of the substrate units and then forming a plurality of slots between adjacent substrate units which is capable of breaking the electrical connections between the electroplating buses and the conductive traces for making the substrate units become independent electrically from each other such that an electrical O/S test can be performed on each of the substrate units before the chip mounting and Molding processes, thereby saving material cost and fabrication cost. Further, since the slots is are filled with a filling material such as an insulating gel or an encapsulant formed through the Molding process in advance, and since the width of the slots is larger than that of the cutting path, after a cutting process is performed between the substrate units along the cutting path passing through the insulating gel or encapsulant of the slots, the cutting surface is remained smooth and the problem of exposure of the conductive traces from the cutting surface can be avoided. As a result, the problems of invasion of moisture and static electricity which adversely degrading the product quality can be avoided. Especially if a laser cut is applied, as the cutting path passes through less part of the substrate unit, such problems as laser melting problem and uneven cutting surface can be avoided.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A fabrication method of a semiconductor package, comprising the steps of:
providing a substrate having a plurality of array arranged substrate units, wherein electroplating buses are disposed between the substrate units, and each substrate unit has a plurality of electrically connecting pads and a plurality of conductive traces for electrically connecting the electrically connecting pads with the electroplating buses such that an electroplating metallic layer can be formed on the electrically connecting pads via the electroplating buses and the conductive traces;
forming slots between the substrate units, for breaking electrical connections between the conductive traces and the electroplating buses;
filling an insulating gel in the slots and drying the insulating gel;
mounting and electrically connecting a semiconductor chip to each of the substrate units;
performing a Molding process so as to form an encapsulant encapsulating the semiconductor chips on the substrate; and
cutting between the substrate units through the slots so as to form a plurality of semiconductor packages.

2. The method of claim 1, wherein a tape is adhered to bottom of the substrate for covering one side of the slots and is then removed after drying of the insulating gel is completed.

3. The method of claim 1, wherein the width of the slots is larger than the width of the cutting path, and the electroplating buses are located within the cutting path.

4. The method of claim 1, wherein the conductive traces are not exposed from the semiconductor packages.

5. The method of claim 1, wherein the conductive traces further comprise ground traces and the slots do not break the electrical connections between the ground traces and the electroplating buses.

6. The method of claim 1, wherein the insulating gel is made of an epoxy resin.

7. A fabrication method of a semiconductor package, comprising the steps of:
providing a substrate having a plurality of array arranged substrate units, wherein electroplating buses are disposed between the substrate units, and each substrate unit has a plurality of electrically connecting pads and a plurality of conductive traces for electrically connecting the electrically connecting pads with the electroplating buses such that an electroplating metallic layer can be formed on the electrically connecting pads via the electroplating buses and the conductive traces;
forming slots between the substrate units, for breaking electrical connections between the conductive traces and the electroplating buses;
mounting and electrically connecting a semiconductor chip to each of the substrate units;
performing a Molding process so as to form an encapsulant encapsulating the semiconductor chips on the substrate and filling the slots; and
cutting between the substrate units through the slots so as to form a plurality of semiconductor packages.

8. The method of claim 7, wherein a tape is adhered to bottom of the substrate for covering one side of the slots and is then removed after the Molding process.

9. The method of claim 7, wherein the width of the slots is bigger than the width of the cutting path, and the electroplating buses are located within the cutting path.

10. The method of claim 7, wherein a plurality of solder balls is mounted on bottom of each of the substrate units such that the semiconductor chip on the substrate unit can be electrically connected with an external device.

11. The method of claim 7, wherein the conductive traces are not exposed from the semiconductor packages.

12. The method of claim 7, wherein the conductive traces further comprise ground traces and the slots does not break the electrical connections between the ground traces and the electroplating buses.

13. An array arranged substrate structure, comprising:
a plurality of array arranged substrate units, wherein each substrate unit has a plurality of electrically connecting pads;
a plurality of electroplating buses arranged in a grid between the substrate units and each substrate unit has conductive traces formed for electrically connecting the electrically connecting pads with the electroplating buses; and
a plurality of slots formed between the substrate units for breaking electrical connections between the conductive traces and the electroplating buses.

14. The structure of claim 13, further comprising a filling material filled in the slots.

15. The structure of claim 14, wherein the filling material is one of an encapsulant and an insulating gel.

16. The structure of claim 15, wherein the insulating gel is made of an epoxy resin.

17. The structure of claim 13, wherein width of the slots is bigger than width of predetermined cutting path between the substrate units, and the electroplating buses are located within the cutting path.

18. The structure of claim 13, wherein the conductive traces further comprise ground traces and the slots do not cut connections between the ground traces and the electroplating buses.

19. A semiconductor package, comprising:
a substrate unit with a plurality of slots formed at least around part of the periphery thereof, a filling material being filled in the slots;
a semiconductor chip mounted on and electrically connected with the substrate unit; and
an encapsulant formed on the substrate unit for encapsulating the semiconductor chip.

20. The semiconductor package of claim 19, wherein the substrate unit has a plurality of electrically connecting pads and a plurality of conductive traces electrically connected with the electrically connecting pads.

21. The semiconductor package of claim 20, wherein the conductive traces are not exposed from the semiconductor package.

22. The semiconductor package of claim 20, wherein the conductive traces further comprise ground traces and the ground traces are not connected to the slots.

23. The semiconductor package of claim 19, further comprising a plurality of solder balls disposed on bottom of the substrate unit.

24. The semiconductor package of claim 19, wherein the filling material is one of an encapsulant and an insulating gel.

25. The semiconductor package of claim 24, wherein the insulating gel is made of an epoxy resin.
